(19) United States
(12) Patent Application Publication
(10) Pub. No.: US 2011/0013369 A1
(43) Pub. Date: Jan. 20, 2011

(54) AUDIO CIRCUIT BOARD

(75) Inventor: Wen-Cheng Lin, Tao Yuan Shien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: QUANTA COMPUTER INC., Tao Yuan Shien (TW)

(21) Appl. No.: 12/607,200

(22) Filed: Oct. 28, 2009

(30) Foreign Application Priority Data
Jul. 15, 2009 (TW) 98123866

(51) Int. Cl. H05K 1/00; H02H 9/00

(52) U.S. Cl. 361/748; 361/56

(57) ABSTRACT

An audio circuit board includes a main body, an audio connector, a digital ground loop, an analog ground portion and a moat. The main body includes an edge and a surface. The audio connector is disposed on one side of the main body and includes a fixing portion. The digital ground loop completely surrounds the edge of the main body. The audio connector is connected with the digital ground loop via the fixing portion. The analog ground portion is disposed on the surface of the main body and is disposed adjacent to the digital ground loop. The analog ground portion is separated from the main body via the moat.

### CROSS REFERENCE TO RELATED APPLICATIONS

This application claims priority of Taiwan Patent Application No. 098123866,filed on Jul. 15, 2009, the entirety of which is incorporated by reference herein.

### BACKGROUND OF THE INVENTION

1. Field of the Invention

The present invention relates to an audio circuit board, and more particularly, to an audio circuit board that decreases electrostatic discharge.

2. Description of the Related Art

FIG. 1 is a schematic view of a conventional audio circuit board. Referring to FIG. 1, a conventional audio circuit board 10 comprises a main body 11, an audio connector 12, a digital ground loop 13, an analog ground portion 14, a moat 15, an audio chip 16, an electrostatic discharge element 17, a short resistance 18, and an inner digital ground portion 19. The audio connector 12 is installed on one side of the main body 11. The digital ground loop 13 partially surrounds the edge of the main body 11, wherein the portion of the edge of the main body 11 near the analog ground portion 14 is not covered by the digital ground loop 13. However, because the analog ground portion 14 is not isolated by the moat 15, static electricity from electronic elements connected to the analog ground portion 14 and the electrostatic discharge element 17 is only conducted to ground by the analog ground portion 14. Compared with the digital ground loop 13 and the inner digital ground portion 19, the area of the analog ground is very small. Thus, when a static electricity test is performed on the conventional audio circuit board, malfunctioning may occur, thus increasing manufacturing costs of the conventional audio circuit board.

### BRIEF SUMMARY OF THE INVENTION

The present invention provides an audio circuit board including a main body, an audio connector, a digital ground loop, an analog ground portion and a moat. The main body includes an edge and a surface. The audio connector is disposed on one side of the main body and includes a fixing portion. The digital ground loop completely surrounds the edge of the main body. The audio connector is connected with the digital ground loop via the fixing portion. The analog ground portion is disposed on the surface of the main body and is disposed adjacent to the digital ground loop. The analog ground portion is separated from the main body via the moat.

Note that the audio circuit board further comprises a ground screw hole. The ground screw hole is disposed between the digital ground loop and the analog ground portion. Also, the audio circuit board further comprises an audio chip, wherein the audio chip is installed on the surface and connected to the moat. Additionally, the audio circuit board further comprises an electrostatic discharge element, wherein the electrostatic discharge element is connected to the digital ground loop and at least a short resistance, wherein the short resistance is installed on the moat. Lastly, the audio circuit board further comprises an inner digital ground portion, wherein the inner digital ground portion is installed on the surface and the short resistance is connected to the inner digital ground portion and the analog ground portion.

### BRIEF DESCRIPTION OF THE DRAWINGS

The present invention can be more fully understood by reading the subsequent detailed description and examples with references made to the accompanying drawings, wherein:

FIG. 1 is a schematic view of a conventional audio circuit board;

FIG. 2 is a schematic view of an audio circuit board of the present invention;

FIG. 3 is a schematic view of an embodiment of an audio circuit board of the present invention; and

FIG. 4 is a schematic view of an embodiment of an audio circuit board of the present invention.

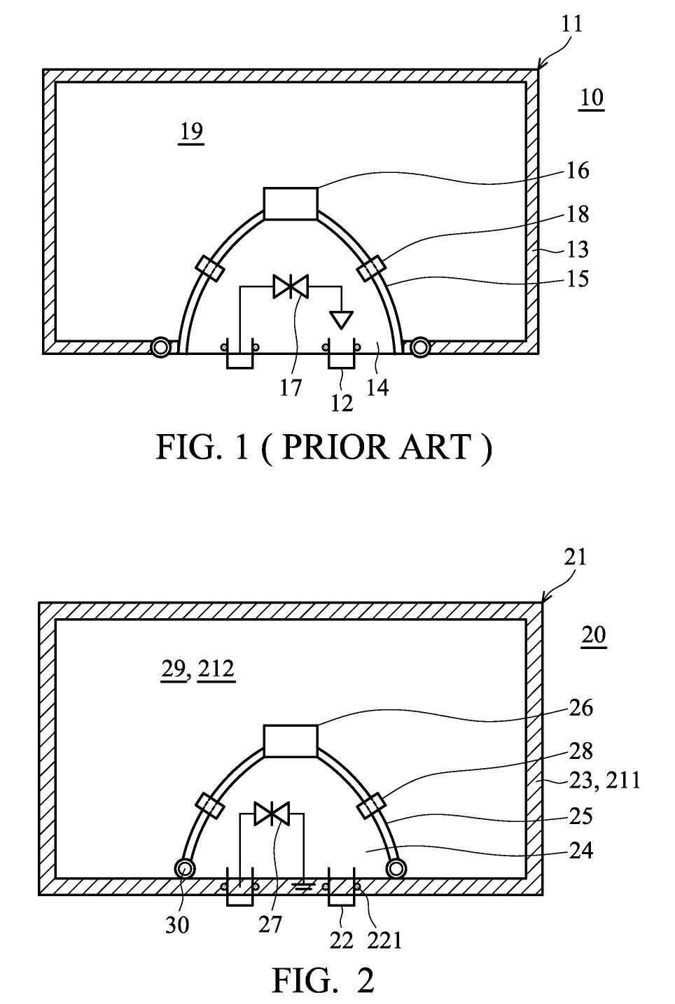

### DETAILED DESCRIPTION OF THE INVENTION

FIG. 2 is a schematic view of an audio circuit board of the present invention.

Referring to FIG. 2, an audio circuit board 20 comprises a main body 21, an audio connector 22, a digital ground loop 23, an analog ground portion 24, a moat 25, an audio chip 26, a electrostatic discharge element 27, a short resistance 28, an inner digital ground portion 29, and a ground screw hole 30.

The main body 21 comprises an edge 211 and a surface 212. The audio connector 22 is inserted to the audio circuit board 20 by earphones (not shown) for electrical connection to the audio circuit board 20. The audio connector 22 is installed on one side of the main body 21 and comprises a fixing portion 221. The audio connector 22 is fixed with the digital ground loop 23 via the fixing portion 221. When the earphones are inserted into or pulled out the audio connector 22, the fixing portion 221 provides fixation to ensure stability of the audio connector 22, avoiding departure or movement.

The digital ground loop 23 completely surrounds the edge 211 of the main body 21. According to the drawing, the digital ground loop 23 completely covers the edge 211 of the main body 21. Compared with the conventional audio circuit board, the edge near the analog ground portion 24 is completely covered. The analog ground portion 24 is installed on the surface 212 of the main body 21 and is adjacent to the digital ground loop 23. Via the moat 25, the analog ground portion 24 is separated from the inner digital ground portion 29 on the main body 21 for differentiating the analog ground portion 24 from the inner digital ground portion 29. The audio chip 26 processes audio signals. The audio chip 26 is installed on the surface 212 and connected to the moat 25. The electrostatic discharge element 27 is connected to the digital ground loop 23 for electrostatic discharging. The short resistance 28 is installed on the moat 25 and connected to the analog ground portion 24 and the inner digital ground portion 29. The ground screw hole 30 is installed between the digital ground loop 23 and the analog ground portion 24 similar to connection of the analog ground portion 24 with the inner digital ground portion 29.

Digital signals are not transmitted via the analog ground portion 24. Thus, even though the audio connector 22 is installed on the digital ground loop 23, there is no noise generated. The digital ground loop 23 of the audio circuit board 20 completely surrounds the whole edge 211 of the main body 21 and the electrostatic discharge element 27 connected to the digital ground loop 23. Thus, static electricity accumulated on the electrostatic discharge element 27 is directly transmitted to the digital ground loop 23. Because the area of the digital ground loop 23 is wide, the discharging area of the present invention is larger than that of the conventional audio circuit board using the analog ground during the electrostatic test. Therefore, the audio circuit board of the inventions does not easily malfunction.

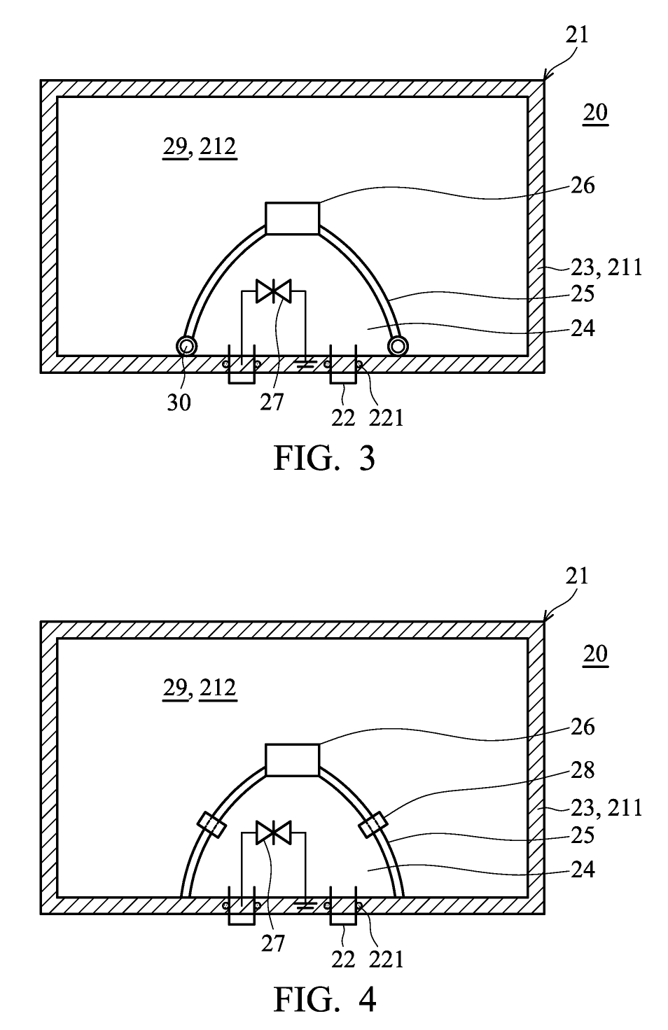

FIG. 3 is a schematic view of an embodiment of an audio circuit board of the present invention. Referring to FIG. 3, this embodiment is similar to that in FIG. 2. The difference is that there is no short resistance 28 installed on the audio circuit board 20 in this embodiment, as the ground screw hole 30 can be used to replace the function of the short resistance 28.

FIG. 4 is a schematic view of an embodiment of an audio circuit board of the present invention. Referring to FIG. 4, this embodiment is similar to that in FIG. 2. The difference is that there is no ground screw hole 30 installed on the audio circuit board 20 in this embodiment, as the short resistance 28 can be used to replace the function of the ground screw hole 30.

In summary, the audio circuit board 20 of the present invention connects the analog ground portion 24 and the electrostatic discharge element 27 to the digital ground loop 23. Thus, static electricity accumulated on the electrostatic discharge element 27 is directly transmitted to the digital ground loop 23. Because the area of the digital ground loop 23 is wide, the discharging area of the present invention is larger than that of the conventional audio circuit board using the analog ground during the electrostatic test. Therefore, the audio circuit board of the inventions does not easily malfunction.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An audio circuit board, comprising:
a main body, comprising an edge and a surface;
an audio connector, disposed on one side of the main body and comprising a fixing portion;
a digital ground loop, completely surrounding the edge of the main body;
an analog ground portion, disposed on the surface of the main body and adjacent to the digital ground loop; and
a moat, separating the analog ground portion from the main body.

2. The audio circuit board as claimed in claim 1, further comprising a ground screw hole, wherein the ground screw hole is disposed between the digital ground loop and the analog ground portion.

3. The audio circuit board as claimed in claim 1, further comprising an audio chip, wherein the audio chip is installed on the surface and connected to the moat.

4. The audio circuit board as claimed in claim 1, further comprising an electrostatic discharge element, wherein the electrostatic discharge element is connected to the digital ground loop.

5. The audio circuit board as claimed in claim 1, further comprising at least a short resistance, wherein the short resistance is installed on the moat.

6. The audio circuit board as claimed in claim 5, further comprising an inner digital ground portion, wherein the inner digital ground portion is installed on the surface, and the short resistance is connected to the inner digital ground portion and
